(19) United States
(12) Patent Application Publication
(10) Pub. No.: US 2026/0050011 A1
(43) Pub. Date: Feb. 19, 2026

(54) CLIP-INTEGRATED POWER MODULE AND METHOD OF MONITORING CURRENT THEREOF

(71) Applicant: HYUNDAI MOBIS CO., LTD., Seoul (KR)

(72) Inventor: Yu Cheol PARK, Yongin-si (KR)

(73) Assignee: HYUNDAI MOBIS CO., LTD., Seoul (KR)

(21) Appl. No.: 19/062,114

(22) Filed: Feb. 25, 2025

(30) Foreign Application Priority Data
Aug. 13, 2024 (KR) 10-2024-0108454

(51) Int. Cl. G01R 1/20; H01C 7/04; H01C 7/06; H01L 23/373

(52) U.S. Cl. CPC G01R 1/203; H01C 7/04; H01C 7/06; H01L 23/3735

(57) ABSTRACT

A clip-integrated power module, a method thereof, and a clip-integrated power system are provided. The clip-integrated power module includes a negative temperature coefficient resistance (NTC) to monitor a temperature of a power module, a shunt resistor to monitor current of the power module, and a clip integrally formed with the NTC and the shunt resistor to electrically connect chips within the power module.

### CROSS-REFERENCE TO RELATED APPLICATION

This application claims priority to and the benefit under 35 USC § 119 of Korean Patent Application No. 10-2024-0108454, filed on Aug. 13, 2024, in the Korean Intellectual Property Office, the entire disclosure of which is hereby incorporated by reference for all purposes as if set forth herein.

### BACKGROUND

### 1. Field

Exemplary embodiments according to the present disclosure relate to a clip-integrated power module and a method of monitoring current thereof,

### 2. Description of the Related Art

Power semiconductor modules are power package modules that supply current to power conversion devices while providing electrical connection, heat dissipation, and electrical insulation functions. The electrical connection generally uses wires and clips, heat dissipation is efficiently managed through a heatsink, and electrical insulation is provided by the internal ceramic of the direct bonded copper (DBC). In addition, a shunt resistor for measuring current and a negative temperature coefficient resistance (NTC) for monitoring temperature are generally required.

The power module needs to provide various functions, which results in the presence of multiple components inside. This may lead to higher manufacturing costs and reliability issues. Accordingly, the present disclosure provides a clip-integrated power module that integrates the NTC and shunt resistor into the clip to address these issues.

### SUMMARY

Various embodiments of the present disclosure are directed to providing a clip-integrated power module that reduces manufacturing costs and improves component reliability by integrating the NTC and shunt resistor of the existing power module into a clip, and a method of monitoring current thereof.

In a general aspect of the disclosure, a clip-integrated power module includes: a negative temperature coefficient resistance (NTC) configured to monitor a temperature of a power module; a shunt resistor configured to monitor current of the power module; and a clip integrally formed with the NTC and the shunt resistor and configured to electrically connect chips within the power module.

The shunt resistor may be formed integrally with the clip by replacing a copper portion bonded to direct bonded copper (DBC) of the power module with the clip.

The NTC is inserted into the copper portion of the shunt resistor and is integrally formed with the shunt resistor and the clip.

The clip is bonded to each of the chips used in parallel when two or more of the chips are used in parallel within the power module.

The clip-integrated power module may further include a processor configured to monitor current of each of the chips through the NTC, individually compare the monitoring results of each of the chips, and detect current imbalance among the chips.

The processor may be further configured to adjust a voltage of the shunt resistor based on the comparison results between a gate voltage of a chip with higher current among the chips and a gate voltage reference, in response to a current imbalance being detected among the chips.

The processor may be further configured to decrease the gate voltage of the chip with higher current in response to the gate voltage thereof being greater than or equal to the gate voltage reference, and increase the gate voltage of the chip with higher current in response to the gate voltage thereof being less than the gate voltage reference.

In another general aspect of the disclosure, a processor-implemented method of monitoring current of a clip-integrated power module, wherein the clip-integrated power module includes a clip configured to be integrally formed with a NTC and a shunt resistor and electrically connect chips within the power module in parallel, includes: monitoring current of each chip within the power module; and comparing individually the monitoring results of each chip and detecting current imbalance among the chips.

The method may further include adjusting a voltage of the shunt resistor based on the comparison results between a gate voltage of a chip with higher current among the chips and a gate voltage reference, in response to a current imbalance being detected in each chip.

The adjusting of the voltage of the shunt resistor may include: decreasing the gate voltage of the chip with higher current in response to the gate voltage thereof being greater than or equal to the gate voltage reference; and increasing the gate voltage of the chip with higher current in response to the gate voltage thereof being less than the gate voltage reference.

In yet another general aspect of the disclosure, a clip-integrated power system, includes: a negative temperature coefficient resistance (NTC) to monitor a temperature of a power module; a shunt resistor to monitor current of the power module; a clip integrally formed with the NTC and the shunt resistor, the clip electrically connected to a plurality of chips within the power module; and a controller configured to control the NTC to monitor current of each of the chips, individually compare the monitoring results of each of the chips, and detect current imbalance among the chips.

The controller may be further configured to adjust a voltage of the shunt resistor based on the comparison results between a gate voltage of a chip with higher current among the chips and a gate voltage reference, in response to a current imbalance being detected among the chips.

The controller may be further configured to: decrease the gate voltage of the chip with higher current in response to the gate voltage thereof being greater than or equal to the gate voltage reference; and increase the gate voltage of the chip with higher current in response to the gate voltage thereof being less than the gate voltage reference.

The shunt resistor may be formed integrally with the clip by replacing a copper portion bonded to direct bonded copper (DBC) of the power module with the clip.

The NTC may be inserted into the copper portion of the shunt resistor and is integrally formed with the shunt resistor and the clip.

The clip may be attached to each of the chips used in parallel when two or more of the chips are used in parallel within the power module.

### BRIEF DESCRIPTION OF THE DRAWINGS

FIG. 1 is a cross-sectional view illustrating a side of a power module according to the related art.

FIG. 2 is a cross-sectional view illustrating a side of a clip-integrated power module according to an embodiment of the present disclosure.

FIGS. 3 and 4 are diagrams illustrating a process of monitoring current flowing through each chip when two or more chips are used in parallel.

FIG. 5 is a flowchart illustrating a method of monitoring current of a clip-integrated power module according to an embodiment of the present disclosure.

### DETAILED DESCRIPTION

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Hereinafter, with reference to the accompanying drawings, embodiments of the present disclosure will be described in detail so that a person skilled in the art can readily carry out the present disclosure. However, the present disclosure may be embodied in many different forms and is not limited to the embodiments described herein.

In the following description of the embodiments of the present disclosure, a detailed description of known functions and configurations incorporated herein will be omitted when it may make the subject matter of the present disclosure rather unclear. Parts not related to the description of the present disclosure in the drawings are omitted, and like parts are denoted by similar reference numerals.

In the present disclosure, components that are distinguished from each other are intended to clearly illustrate each feature. However, it does not necessarily mean that the components are separate. That is, a plurality of components may be integrated into one hardware or software unit, or a single component may be distributed into a plurality of hardware or software units. Thus, unless otherwise noted, such integrated or distributed embodiments are also included within the scope of the present disclosure.

In the present disclosure, components described in the various embodiments are not necessarily essential components, and some may be optional components. Accordingly, embodiments consisting of a subset of the components described in one embodiment are also included within the scope of the present disclosure. In addition, embodiments that include other components in addition to the components described in the various embodiments are also included in the scope of the present disclosure.

Hereinafter, with reference to the accompanying drawings, embodiments of the present disclosure will be described in detail so that a person skilled in the art can readily carry out the present disclosure. However, the present disclosure may be embodied in many different forms and is not limited to the embodiments described herein.

In the following description of the embodiments of the present disclosure, a detailed description of known functions and configurations incorporated herein will be omitted when it may make the subject matter of the present disclosure rather unclear. Parts not related to the description of the present disclosure in the drawings are omitted, and like parts are denoted by similar reference numerals.

In the present disclosure, when a component is referred to as being “linked,” “coupled,” or “connected” to another component, it is understood that not only a direct connection relationship but also an indirect connection relationship through an intermediate component may also be included. In addition, when a component is referred to as “comprising” or “having” another component, it may mean further inclusion of another component not the exclusion thereof, unless explicitly described to the contrary.

In the present disclosure, the terms first, second, etc. are used only for the purpose of distinguishing one component from another, and do not limit the order or importance of components, etc., unless specifically stated otherwise. Thus, within the scope of this disclosure, a first component in one exemplary embodiment may be referred to as a second component in another embodiment, and similarly a second component in one exemplary embodiment may be referred to as a first component.

In the present disclosure, components that are distinguished from each other are intended to clearly illustrate each feature. However, it does not necessarily mean that the components are separate. That is, a plurality of components may be integrated into one hardware or software unit, or a single component may be distributed into a plurality of hardware or software units. Thus, unless otherwise noted, such integrated or distributed embodiments are also included within the scope of the present disclosure.

In the present disclosure, components described in the various embodiments are not necessarily essential components, and some may be optional components. Accordingly, embodiments consisting of a subset of the components described in one embodiment are also included within the scope of the present disclosure. In addition, exemplary embodiments that include other components in addition to the components described in the various embodiments are also included in the scope of the present disclosure.

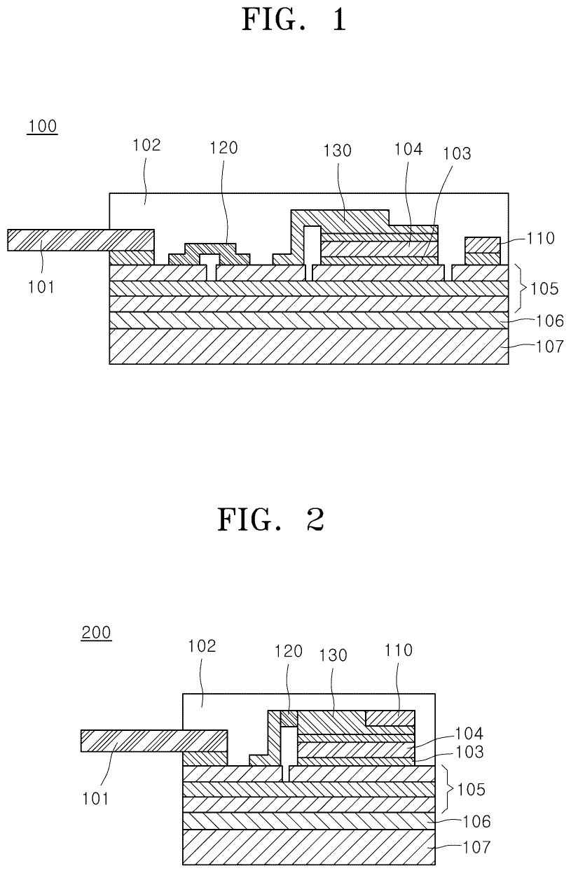

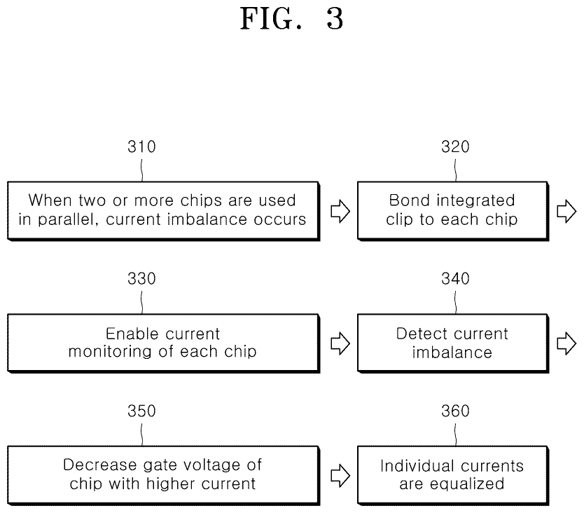

FIG. 1 is a cross-sectional view illustrating a side of a power module according to the related art. FIG. 2 is a cross-sectional view illustrating a side of a clip-integrated power module according to an embodiment of the present disclosure.

A clip-integrated power module 200 illustrated in FIG. 2 may be configured to include a terminal 101, an EMC 102, a solder 103, a chip 104, a DBC 105, a TIM 106, a heatsink 107, an NTC 110, a shunt resistor 120, and a clip 130, similar to the existing power module illustrated in FIG. 1.

However, the clip-integrated power module 200 differs from the power module 100 of FIG. 1 in that the NTC 110, shunt resistor 120, and clip 130 are integrally formed.

That is, the existing power module 100 has disadvantages in terms of price, reliability, and volume because the NTC 110, shunt resistor 120, and clip 130 are formed separately. The power module is essential as it should provide fundamental functions including temperature monitoring, current monitoring, and electrical connection.

To overcome these existing disadvantages, the present disclosure may improve the structure by integrating three separate components, NTC 110, shunt resistor 120, and clip 130, provided in the power module as illustrated in FIG. 2, into a single integrated component. This integration may improve efficiency in terms of price, reliability, and volume.

That is, the shunt resistor 120 primarily has a copper portion that bonds to the DBC 105 with specific resistance, thereby providing properties similar to those of the clip 130. In addition, the shunt resistor 120, which is primarily responsible for electrical connections, may be used as a clip replacement.

The NTC 110 may be inserted into the copper portion of the shunt resistor 120. As a result, the NTC 110, shunt resistor 120, and clip 130 are integrally formed in the power module 200 of the present disclosure, thereby providing advantages in terms of price, reliability, and volume. These advantages are described in detail as follows.

First, using a single integrated component reduces manufacturing costs.

The NTC 110, shunt resistor 120, and clip 130 need to be bonded to the DBC 105 or chip 104, and this may be achieved with a single bonding process. As a result, the cost of materials such as the solder 103, may also be reduced.

Second, using a single integrated component improves reliability.

According to reliability engineering, as the number of components increases, the probability of failure also increases. However, when a single integrated component is used, as in the present disclosure, the number of components is reduced, which lowers the probability of failure, and thus improves reliability.

Third, using a single integrated component provides efficient volume utilization.

Comparing FIGS. 1 and 2, the space of the NTC 110 and the shunt resistor 120 is integrated with the clip 130 to improve space utilization. As a result, it is volumetrically efficient.

Fourth, using a single integrated component prevents current imbalance.

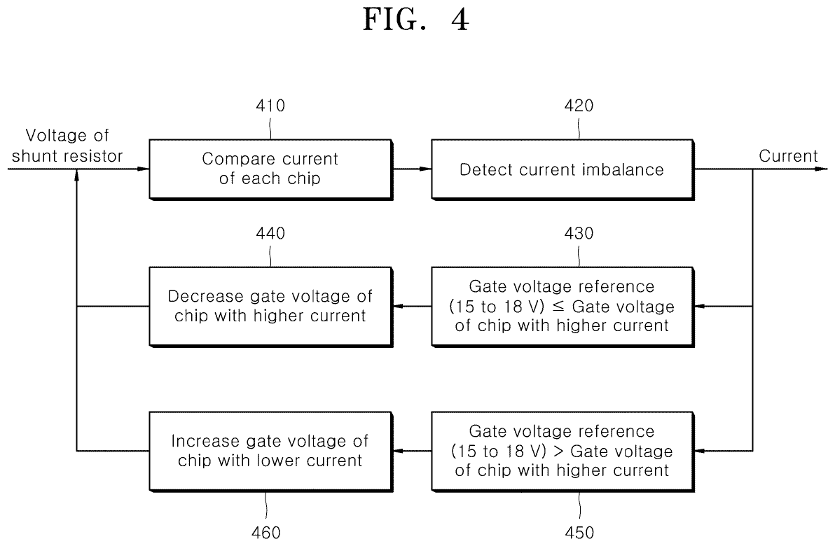

When two or more chips are used in parallel, integrating the NTC 110, shunt resistor 120, and clip 130 as a single component allows for monitoring the current flowing through each chip, thereby preventing current imbalance. This will be described later with reference to FIGS. 3 and 4.

Each of the integrated components, NTC 110, shunt resistor 120, and clip 130, will be described in detail below.

The NTC 110 may measure the temperature of the power module 200 by utilizing the thermal resistance of the power module 200. The NTC 110 is referred to as a negative temperature coefficient resistance because a resistance value thereof decreases as the temperature increases. For example a circuitry may include the NTC 110 to monitor the temperature of the power module 200.

The NTC 110 has a high temperature coefficient of resistance, allowing for precise temperature measurement and fast response. In addition, the NTC 110 has a simple structure that allows for miniaturization and is insensitive to pressure, magnetism, and other factors. In addition, the NTC 110 may be supplied in large quantities at a stable price and has excellent mechanical strength and machinability.

The NTC 110 may be used in inverters. In the case of SiC chips without a temperature sensor, the inverter uses the NTC 110 to measure the relationship between resistance and temperature, and this is used for current limiting or temperature limiting functions.

The shunt resistor 120 may measure the current of the power module 200 based on the voltage across the resistor. For example, a circuitry including the shunt resistor 120 may monitor the current of the power module 200.

As such, the shunt resistor 120 is used for current measurement. A resistor with a very low resistance value is generally referred to as a shunt resistor. The primary purpose of the shunt resistor 120 is to measure current, which is achieved by placing a resistor in series within the current-carrying wire and measuring the voltage generated across the resistor.

The shunt resistor 120 is inexpensive, has a very low resistance value, and has high density characteristics. In addition, the shunt resistor 120 enables simple current measurement and exhibits minimal resistance variation at high temperatures.

The shunt resistor 120, like the NTC 110, may be used in inverters. The inverter may use a current transformer (CT) to measure current, but the shunt resistor 120 is also used to reduce costs.

The clip 130 may be used to electrically connect the chips within the power module 200. The clip 130 is suitable for high-power solutions, has superior reliability compared to wire bonding, and is heat dissipative.

The clip 130 may be integrally formed with the NTC 110 and the shunt resistor 120. To accomplish this, the shunt resistor 120 may be integrally formed with the clip 130 by replacing the copper portion bonded to the DBC 105 of the power module 200 with the clip 130. For example, a circuitry including the clip 130, the NTC 110, and the shunt resistor 120 may be integrally formed, with the clip 130 electrically connecting the chips within the power module 200.

In addition, the NTC 110 may be inserted into the copper portion of the shunt resistor 120 and integrally formed with the shunt resistor 120 and the clip 130.

The integrally formed clip 130 may be configured to bond to each chip when two or more chips are used in parallel within the power module 200.

As such, in the present disclosure, the existing issues of cost and reliability may be addressed by manufacturing the NTC 110, shunt resistor 120, and clip 130 of the existing power module 100 as an integrated component of the power module 200.

That is, in the present disclosure, the manufacturing cost of the power module 200, which integrates the NTC 110, shunt resistor 120, and clip 130 into a single component, is lower than that of the power module 100, which includes these three separate components, NTC 110, shunt resistor 120, and clip 130, thereby reducing costs.

In addition, in the present disclosure, the reliability of the power module 200, which integrates the NTC 110, shunt resistor 120, and clip 130 into a single component, is higher than that of the power module 100, which includes these three components, NTC 110, shunt resistor 120, and clip 130, thereby improving reliability.

For example, if a reliability test pass rate of each of the NTC 110, shunt resistor 120, and clip 130 is 95%, a reliability test pass rate of the three-component power module 100 is 85.7%, whereas a reliability test pass rate of the single integrated power module 200 is 95%.

FIG. 3 is a diagram illustrating current imbalance and a method of preventing current imbalance when two or more chips within the power module are used in parallel, according to an embodiment of the present disclosure.

As illustrated in FIGS. 2 and 3, when two or more chips 104 are used in parallel, current imbalance may occur (310). To address this, in the present disclosure, the integrated clip 130 may be bonded to each chip 104 (320).

This bonding of the integrated clip 130 to each chip 104 enables current monitoring of each chip 104 (330). When current imbalance is detected through current monitoring (340), in the present disclosure, the gate voltage of the chip 104 with higher current is decreased (350), thereby equalizing the individual currents (360).

FIG. 4 is a flowchart illustrating a process of monitoring current of a clip-integrated power module according to an embodiment of the present disclosure. For reference, the current monitoring process may be performed by a processor included in the clip-integrated power module.

Referring to FIGS. 2 and 3, the processor may monitor the current of each chip 104 within the power module 200 when two or more chips 104 are used in parallel, based on the voltage of the shunt resistor 120, and individually compare the monitoring results of each chip 104 (410).

Next, the processor may detect the current imbalance among the chips 104 based on the comparison results of the currents of each chip 104 (420). In other words, the processor may compare the current values of each chip 104 and detect current imbalance among the chips 104 if the difference exceeds a predefined reference value.

In this case, if the gate voltage of the chip 104 with higher current among the chips 104 is greater than or equal to the gate voltage reference (e.g., 15 V to 18 V) (430), the processor may decrease the gate voltage of the chip 104 with higher current (440).

On the other hand, if the gate voltage of the chip 104 with higher current among the chips 104 is less than the gate voltage reference (e.g., 15 V to 18 V) (450), the processor may increase the gate voltage of the chip 104 with higher current (460).

As such, in the embodiment of the present disclosure, even when two or more chips 104 are used in parallel, the use of the clip-integrated power module 200 allows for monitoring the current flowing through each chip 104, thereby preventing current imbalance in advance.

In this case, the processor may perform each process operation through instructions stored in memory. The memory may store at least one instruction executed by the processor.

The memory may be implemented as internal memory, such as ROM included in the processor (e.g., electrically erasable programmable read-only memory (EEPROM)), RAM, or as memory separate from the processor.

In this case, the memory may be implemented in the form of memory embedded in the power module 200 or in the form of memory that is detachably attached to the power module 200, depending on the purpose of data storage.

For example, data for driving the power module 200 may be stored in memory embedded in the power module 200, and data for expansion functions of the power module 200 may be stored in memory detachably that is attached to the power module 200.

In this case, the memory embedded in the power module 200 may be implemented as at least one of the following: volatile memory (e.g., dynamic RAM (DRAM), static RAM(SRAM), or synchronous dynamic RAM (SDRAM)), non-volatile memory (e.g., one-time programmable ROM (OTPROM), programmable ROM (PROM), erasable and programmable ROM (EPROM), electrically erasable and programmable ROM (EEPROM), mask ROM, flash ROM, flash memory (e.g., NAND flash or NOR flash), hard drive, or solid-state drive (SSD).

In addition, the memory that is detachably attached to the power module 200 may be implemented in the form of a memory card (e.g., compact flash (CF), secure digital (SD), micro secure digital (Micro-SD), mini secure digital (Mini-SD), extreme digital (xD), multi-media card (MMC), etc.), external memory that may be connected to a USB port (e.g., USB memory), etc.

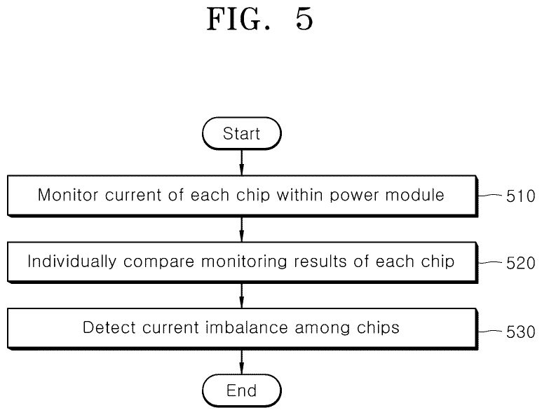

FIG. 5 is a flowchart illustrating a method of monitoring current of a clip-integrated power module according to an embodiment of the present disclosure.

A method of monitoring current of a clip-integrated power module according to an embodiment of the present disclosure may be performed by the processor described above.

In addition, the method of monitoring current of a clip-integrated power module according to the embodiment of the present disclosure is only an example of the present disclosure, and various other steps may be added as needed, as described below. Furthermore, the following steps may also be performed in a different order, so that the present disclosure is not limited to each of the steps and the order thereof as described below.

Referring to FIGS. 2 and 5, in step 510, the processor may monitor the current of each chip 104 within the power module 200.

Specifically, when two or more chips 104 within the power module 200 are used in parallel, the processor may monitor the current of each chip 104 based on the voltage of the shunt resistor 120.

Next, in step 520, the processor may individually compare the monitoring results of the currents of each chip 104.

Next, in step 530, the processor may detect the current imbalance among the chips 104 based on the comparison results of the currents of each chip 104.

In other words, the processor may compare the current values of each chip 104 and detect the current imbalance among the chips 104 if the difference exceeds a predefined reference value.

If current imbalance is detected, the processor may adjust the current imbalance based on gate voltage reference data (e.g., 15 V to 18 V) stored in memory.

For example, if the gate voltage of the chip 104 with higher current among the chips 104 is greater than or equal to the gate voltage reference (e.g., 15 V to 18 V), the processor may adjust the current imbalance among the chips 104 within the power module 200 by decreasing the gate voltage of the chip 104 with higher current.

On the other hand, if the gate voltage of the chip 104 with higher current among the chips 104 is less than the gate voltage reference (e.g., 15 V to 18 V), the processor may adjust the current imbalance among the chips 104 within the power module 200 by increasing the gate voltage of the chip 104 with higher current.

As such, in the embodiment of the present disclosure, even when two or more chips 104 are used in parallel, the use of the clip-integrated power module 200 allows for monitoring the current flowing through each chip 104, thereby preventing current imbalance in advance.

What is claimed is:

1. A clip-integrated power module comprising:
a negative temperature coefficient resistance (NTC) configured to monitor a temperature of a power module;
a shunt resistor configured to monitor current of the power module; and
a clip integrally formed with the NTC and the shunt resistor and configured to electrically connect chips within the power module.

2. The clip-integrated power module of claim 1, wherein the shunt resistor is formed integrally with the clip by replacing a copper portion bonded to direct bonded copper (DBC) of the power module with the clip.

3. The clip-integrated power module of claim 2, wherein the NTC is inserted into the copper portion of the shunt resistor and is integrally formed with the shunt resistor and the clip.

4. The clip-integrated power module of claim 1, wherein the clip is bonded to each of the chips used in parallel when two or more of the chips are used in parallel within the power module.

5. The clip-integrated power module of claim 4, further comprising:
a processor configured to:
monitor current of each of the chips through the NTC;
individually compare the monitoring results of each of the chips; and
detect current imbalance among the chips.

6. The clip-integrated power module of claim 5, wherein the processor is further configured to adjust a voltage of the shunt resistor based on the comparison results between a gate voltage of a chip with higher current among the chips and a gate voltage reference, in response to a current imbalance being detected among the chips.

7. The clip-integrated power module of claim 6, wherein the processor is further configured to:
decrease the gate voltage of the chip with higher current in response to the gate voltage thereof being greater than or equal to the gate voltage reference; and
increase the gate voltage of the chip with higher current in response to the gate voltage thereof being less than the gate voltage reference.

8. A processor-implemented method of monitoring current of a clip-integrated power module, wherein the clip-integrated power module includes a clip configured to be integrally formed with a NTC and a shunt resistor and electrically connect chips within the power module in parallel, the method comprising:
monitoring current of each chip within the power module; and
comparing individually the monitoring results of each chip and detecting current imbalance among the chips.

9. The method of claim 8, further comprising:
adjusting a voltage of the shunt resistor based on the comparison results between a gate voltage of a chip with higher current among the chips and a gate voltage reference in response to a current imbalance being detected in each chip.

10. The method of claim 9, wherein the adjusting of the voltage of the shunt resistor comprises:
decreasing the gate voltage of the chip with higher current in response to the gate voltage thereof being greater than or equal to the gate voltage reference; and
increasing the gate voltage of the chip with higher current in response to the gate voltage thereof being less than the gate voltage reference.

11. A clip-integrated power system, comprising:
a negative temperature coefficient resistance (NTC) configured to monitor a temperature of a power module;
a shunt resistor configured to monitor current of the power module;
a clip integrally formed with the NTC and the shunt resistor and configured to electrically connect chips within the power module; and
a controller configured to:
control the NTC to monitor current of each of the chips;
individually compare the monitoring results of each of the chips; and
detect current imbalance among the chips.

12. The system of claim 11, wherein the controller is further configured to adjust a voltage of the shunt resistor based on the comparison results between a gate voltage of a chip with higher current among the chips and a gate voltage reference, in response to a current imbalance being detected among the chips.

13. The system of claim 12, wherein the controller is further configured to:
decrease the gate voltage of the chip with higher current in response to the gate voltage thereof being greater than or equal to the gate voltage reference; and
increase the gate voltage of the chip with higher current in response to the gate voltage thereof being less than the gate voltage reference.

14. The system of claim 11, wherein the shunt resistor is formed integrally with the clip by replacing a copper portion bonded to direct bonded copper (DBC) of the power module with the clip.

15. The system of claim 14, wherein the NTC is inserted into the copper portion of the shunt resistor and is integrally formed with the shunt resistor and the clip.

16. The system of claim 11, wherein the clip is attached to each of the chips used in parallel when two or more of the chips are used in parallel within the power module.
